(19) United States
(12) Patent Application Publication
(10) Pub. No.: US 2012/0133029 A1
(43) Pub. Date: May 31, 2012

(54) METHOD OF NANOSTRUCTURING A FILM OR A WAFER OF MATERIAL OF THE METAL OXIDE OR SEMI-CONDUCTOR TYPE

(75) Inventors: Gilles Lerondel, Saint Julien Les Villes (FR); Laurent Divay, Ivry Sur Seine (FR)

(73) Assignee: UNIVERSITE DE TECHNOLOGIE DE TROYES, Troyes (FR)

(21) Appl. No.: 13/319,755

(22) PCT Filed: May 12, 2010
(86) PCT No.: PCT/FR2010/050936

§ 371 Date: Feb. 15, 2012

(30) Foreign Application Priority Data
May 14, 2009 (FR) 0902339

(51) Int. Cl. H01L 29/06; H01L 21/20; B82Y 40/00; B82Y 99/00

(52) U.S. Cl. 257/618; 438/478; 977/811; 977/813; 257/E29.024; 257/E21.09

(57) ABSTRACT

A method for nanostructuring a film (2) of material includes a step of immersing the film (2) of material in an aqueous solution (3), during which an interference FIG. 6) including illuminated areas (6b) and dark areas (6a) is applied to at least one of the faces of the film (2). The material is a semiconductor inorganic material or oxide, which is able to be solubilised in aqueous solution under the effect of the absorption of light. The nanostructuring of the film (2) is effected, at its surface in contact with the aqueous solution (3), by photodissolution in the illuminated areas (6a) and/or by growth in the dark areas (6b) of the interference FIG. 6). Also described is a nanostructured coating film (5) obtained according to such a preparation method, as well as a nanostructured 3D film.

The present invention relates generally to the field of the direct nanostructuring, on large surfaces, of a material of the metal oxide or semiconductor (SC) type (for example zinc oxide) in the form of a film or wafer, for producing passive or active optical elements or any other element requiring structuring of this type (sensor, electrical device, etc).

Nanostructuring means, within the meaning of the present application, structuring leading to the formation of nanostructures, that is to say structures having submicron or nanometric dimensions. It is however understood that a person skilled in the art is in a position to implement variants of the invention with structures having micrometric dimensions without for all that departing from the scope of the patent. Such nanostructuring is based on the use of the photochemical properties of the material, which makes it possible, when it is combined with holography, to dissolve and/or synthesise a material (film or wafer).

Direct nanostructuring means, within the meaning of the present application, nanostructuring in a single step, for example by dissolution, in contradistinction to nanostructuring by dissolution of a photosensitive resin, where insolation and then transfer is carried out.

Film means, within the meaning of the present application, a thin film on substrate or a solid material such as a wafer.

Zinc oxide is currently the subject of numerous researches, in particular relating to the optical emission properties thereof.

One way of optimising the optical properties thereof is to nanostructure the zinc oxide (ZnO).

This is because, in the field of optics, nanostructuring optimises the extraction of light from the material: increasing the useful light flux (redistribution of the emission diagram), a larger number of photons emitted (modification of the emission probability via Purcell effect—photon crystal approach), increase in the oscillating force and control of the position of the emission (quantum confinement), reduction in stimulated emission thresholds (retroactive effect).

In addition to these emission properties, zinc oxide can also be used as a contact electrode (conductive transparent oxide), as a piezoelectric element, as a photodetector (UV photodiode), or a sensor. By way of example, nanostructuring can for example be used for increasing the coupling efficacy (antireflection effect, adaptation of index, increase in absorption) in the case of photodiodes or photovoltaic cells, or increasing the specific surface in the case of sensors.

To carry out this nanostructuring of zinc oxide, several techniques are known, which are essentially divided into three categories.

A first category groups together techniques consisting of performing indirect lithography by means of a mask, followed by a step of transfer into the thin film of material, for example by electron lithography followed by a dry etching step or by microscopic-scale photolithography. This lithography technique does however have the drawback of using a mask, which acquires the use of numerous steps associated with this mask.

A second category groups together techniques consisting of direct lithography, for example high-resolution lithography by focussed ion beam, or by direct microscopic-scale photodissolution. The first technique makes it possible to obtain high-resolution structuring, but the structured surface remains limited to dimensions of around 100 μm×100 μm, which makes it impossible to manufacture such structures on a large scale.

A third category groups together techniques consisting of causing a growth of lattices of nanostructures of nanostructured films (random structuring in the plane) by chemical, electrochemical or thermal synthesis. The patent application US 2008/107876 describes in particular a method for the selective growth of zinc oxide microstructures, which comprises a step of applying a material to a substrate, a step of forming a pattern having a predetermined and specific position and a predetermined interval on the substrate, using a physical or chemical etching technique, and a step of selective growth of zinc oxide microstructures at the position where the pattern is formed, using various growth techniques such as hydrothermal synthesis, or physical or chemical deposition by evaporation.

These techniques use a chemical, electrochemical or thermal synthesis making it possible to produce large nanostructured surfaces, but the structuring in the plane is random. It is possible to overcome this drawback by combining this technique with those of mask lithography, in order to obtain structuring on large surfaces, but there then remains the problem of the manufacture of the mask.

None of these techniques is used at an industrial level.

Thus there does not exist today any method enabling certain materials such as zinc oxide to be nanostructured, that is simple, direct and controlled and can be carried out on large surfaces, while having available structuring of excellent quality. It should be stated that this problem is not specific to ZnO.

The aim of the present invention is to remedy this technical problem, using the photochemical and electrochemical properties of certain materials, such as zinc oxide, combined with holography.

For this purpose, the applicant has developed a method that makes it possible to obtain, in a simple, direct and controlled manner, films (mono- or multilayer) that are nanostructured to submicron scale (a measurement scale that groups together the dimensions less than a micrometre lying between 100 and 1000 nanometres) and nanometric scale (the measurement scale that groups together the dimensions less than a hundred nanometres), on large surfaces, dispensing completely with the use of a lithography mask.

More particularly, the subject matter of the invention is therefore a method for nanostructuring a film of material, comprising a step of immersing said film of material in an aqueous solution, during which there is applied, to at least one of the faces of the film, an interference figure comprising illuminated areas and dark areas, said method being characterised in that:
said material is a semiconductor inorganic material or oxide, which is able to be solubilised in an aqueous solution under the effect of the absorption of light (the wavelength of which is therefore less than the prohibited band of the material) and
the nanostructuring of the film or wafer of material takes place, at the surface of the film in contact with the aqueous solution, by photodissolution in said illuminated areas and/or by growth in said dark areas of said interference figure.

The materials that are used in the method according to the invention comprise any type of inorganic or semiconductor material that is able to be solubilised in an aqueous solution under the effect of the absorption of light. In other words, the wavelength of the light radiation is such that it allows the generation of charge carriers within the material immersed in the aqueous etching solution (pH preferably between 6 and 12), leading to an increase in the rate of dissolution of said material.

Charge carriers means, within the meaning of the present invention, electrons or holes.

By way of examples of materials that can be used in the context of the present invention, zinc oxide ZnO will in particular be cited.

Apart from zinc oxide, other materials may be used, such as gallium nitride GaN, gallium arsenide GaAs or gallium phosphide GaP. Other semiconductor materials such as tin oxide or titanium oxide may be used.

Preferably ultraviolet (for example 375 nanometres or less) will be used for producing the hologram and therefore generating small patterns. This is true also for materials with small prohibited bands.

In addition, since it is a case of a direct structuring process (direct etching is spoken of if the main mechanism involved is photodissolution), the surface thus treated is limited only by the spatial extension of the beam, which depends only on the match between the laser power used and the dose necessary for etching (or the inhibition of growth where applicable).

The material to be nanostructured preferably comprises zinc oxide. Thus it is possible to use the photochemical and electrochemical properties of zinc oxide combined with holography, which improves the quality of the structure obtained according to this method. More preferably, the nanostructure material consists entirely of zinc oxide.

The film of material to be nanostructured is, in the context of the present invention, in the form of a thin film (which may be mono- or multilayer) deposited on a substrate (in particular a monocrystalline substrate of the silicon or sapphire type, or a vitreous substrate of the glass or silica type) or a solid material such as a wafer.

The film of material may for example be in the form of a photosensitive wafer, in particular of zinc oxide, or in the form of a mono- or multilayer film obtained by successive depositions, on a substrate, of thin layers that are etched afterwards.

The film is preferably non-porous, so that any phenomenon of dissolution or growth takes place at the face or faces of the film or wafer situated in contact (by immersion) with the aqueous solution.

To produce the interference figure, a holography device may be used. Such a device, well known to persons skilled in the art, comprises a light source illuminating:
firstly an object so that part of the light is diffracted towards the face of the film or wafer to be nanostructured, in immersion in an aqueous solution, and
secondly, a mirror so as to interfere with said diffracted light while serving as a reference.

It is thus possible to obtain an interference figure parameterisable by the object illuminated.

A simple case consists of using a mirror as the object. There is then obtained, after adjustment of the optical path differences, a one-dimensional (1D) interference figure in this case in the form of a alternation of dark fringes and illuminated fringes.

Any technique of producing an interference figure may be used here. Whatever the technique used, it is possible to make the nanostructure more complex by multiplying the number of exposures or the number of beams (for example four-beam interference to make a square lattice).

Thus it is also possible to generate planar (1D) or square, hexagonal, or even higher symmetry (fifth order, twelfth order) lattices. The latter lattices also make the emission diagram homogenised.

The nanostructuring of the film material then takes place by photodissolution in the illuminated areas of the interference figure or by growth in the dark areas of this interference figure (but the solutions used are not the same).

According to a first variant of the invention, the nanostructuring is obtained by local etching. The film is immersed in an aqueous solution the pH of which is preferably between 6 and 12. The nanostructuring takes place by photodissolution in the illuminated areas of the interference figure.

According to a second variant of the invention, the nanostructure is obtained by local growth. The film is immersed in a solution allowing growth of a material. The nanostructuring takes place by inhibition of growth in the illuminated areas.

In the first variant embodiment, the etching is more rapid in the illuminated areas, and in the second variant the growth is more rapid in the dark areas.

Thus the generation of a light pattern (consisting of the interference figure) on the surface of the material immersed in an aqueous solution generates the topology corresponding to the pattern in the material by direct photodissolution (in this case the etching is more rapid in the illuminated areas) and/or by growth (in this case the crystallisation is more rapid in the dark areas).

In the case of photodissolution, this will be all the more selective, the lower the concentration of the three carriers (the carriers are in this case solely generated by absorption of a photon, and their density is therefore highly dependent on the local intensity of the interference figure).

Moreover, the dissolution can take place either chemically, or electrochemically (application of a potential typically of +1V with respect to an Ag/AgCl reference electrode). The dissolution dynamics is considerably increased, in certain cases by a factor of 10 or even more.

The method according to the invention can be repeated in series: deposition, then photoetching, then further deposition, then further photoetching etc. This then makes it possible to make stacks of nanostructured layers.

Numerous applications (in particular relating to lighting, display and sensor technology) relate to nanostructuring on large surfaces, since it is a case of structuring to submicron (or even micron) or nanometric scales, which is at the same time simple, rapid and compatible with large-scale production.

The invention also concerns a film or wafer with a nanostructured coating capable of being obtained in accordance with the preparation method according to the invention as described above.

Finally, another subject matter of the present invention is a three-dimensional nanostructured coating film. In the case of such a film, the depth of etching depends on the local light intensity. For example, according to the number of exposures N, there will be areas illuminated zero times, once, . . . N times. This results in differences in height in terms of z.

Other advantages and particularities of the present invention will emerge from the following description given by way of non-limitative example and made with reference to the accompanying figures:

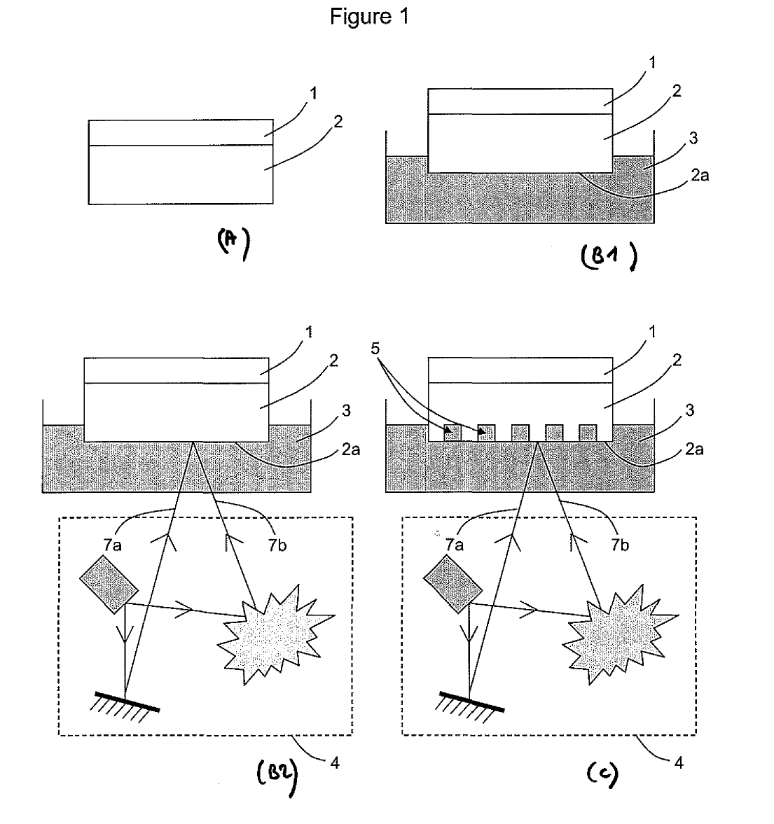

FIG. 1 shows a succession of diagrams illustrating the various steps of the nanostructuring method according to the invention in accordance with a first embodiment,

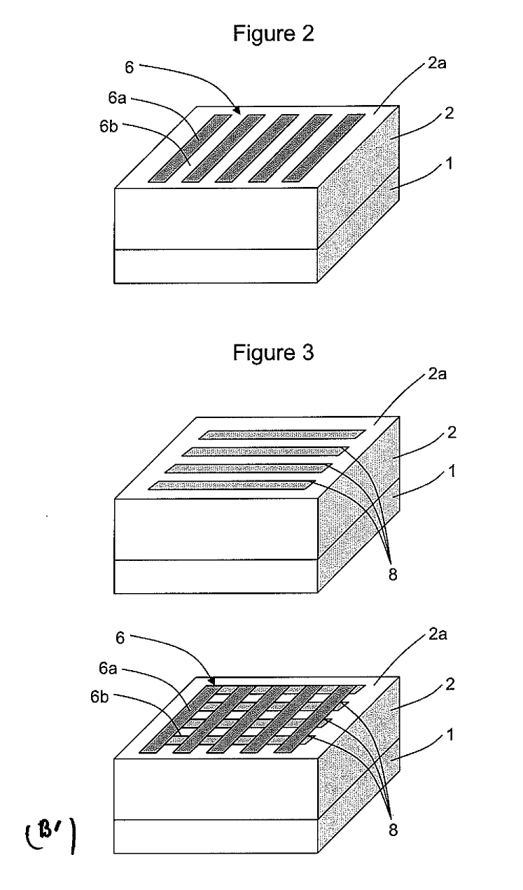

FIG. 2 shows a schematic perspective view of the material during the step of generating the interference figure according to the embodiment of the method in accordance with the invention illustrated in FIG. 1,

FIG. 3 shows a succession of two schematic perspective views illustrating two steps of the nanostructuring method according to the invention in accordance with a second embodiment, which comprises in particular a step of forming an additional periodic topology, and

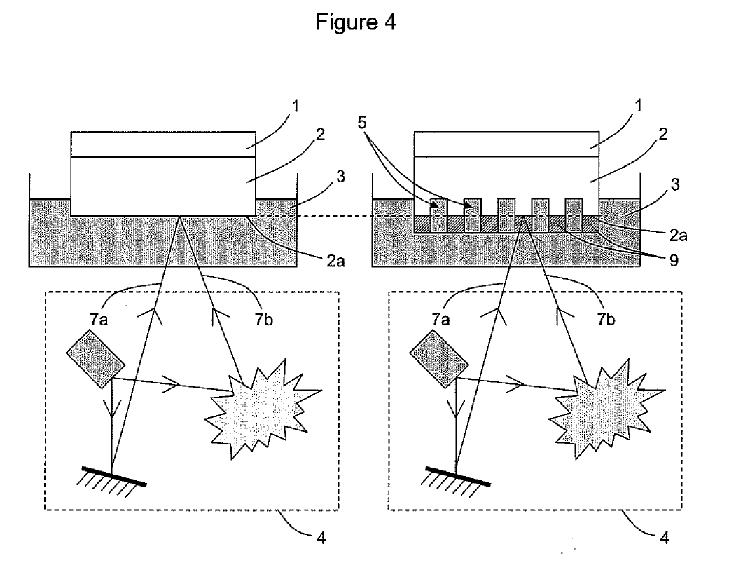

FIG. 4 shows a succession of two schematic perspective views illustrating two steps of the nanostructuring method according to the invention in accordance with a third embodiment, in which there are a photodissolution mechanism in the illuminated areas of the interference figure and a growth mechanism in the dark areas.

The identical elements shown in FIGS. 1 to 4 are identified by identical numerical references.

### 1^{ST} EMBODIMENT OF THE METHOD ACCORDING THE INVENTION (WITH REFERENCE TO FIGS. 1 AND 2)

FIG. 1 (and also FIG. 2) shows schematically the various steps of the nanostructuring method according to the invention in accordance with a first embodiment:
A) formation, on a substrate 1, of a film 2 of zinc oxide ZnO, which is known for its suitability for being solubilised in aqueous solution under the effect of the absorption of light the wavelength of which is less than the prohibited band of ZnO, which allows the generation of charge carriers in the zinc oxide film and therefore makes it possible to increase the speed of dissolution thereof in the aqueous solution;
B1) immersion of the film 2 of zinc oxide in an aqueous solution 3, which has a pH able to effect the chemical etching of the material. In the case of zinc oxide the pH will preferentially be between 6 and 12 (in this way direction dissolution in the black is minimised), this immersion being performed so that at least the face of the film 2 (the one that is not in contact with the substrate 1) is completely immersed in the aqueous solution 3,
B2) during immersion, the application, on at least one of the faces of the film 2, of an interference FIG. 6 comprising illuminated areas 6a and dark areas 6b,
which leads to the nanostructuring C) of the film 2 of ZnO, at the surface of the film 2 in contact with the aqueous solution 3, by photodissolution in said illuminated areas (6a) of said interference FIG. 6).

With regard more particularly to step B1 (immersion of the film 2 of zinc oxide in an aqueous solution 3), an aqueous solution 2 is used the pH of which enables the zinc oxide to be dissolved.

A suitable aqueous solution could be of the following formula: 0.1 M NaCl+0.1 M NaOH+0.1 M HCl. Hydrogen chloride HCl makes it possible here to adjust the pH.

Other aqueous solutions make be envisaged, in particular chemical etching by an acid (HCl, HNO₃, H₃PO₄), or by an acidic salt (FeCl₃.6H₂O), or by a solution of iron chloride (FeCl₃.6H₂O): 0.8 mmol FeCl₃.6H₂O+100 mL H₂O (8 mM).

With regard more particularly to step B2(application, to at least one of the faces of the film 2 of zinc oxide, of an interference FIG. 6), the following procedure is followed:
the surface 2a of the film 2 (immersed in the aqueous solution 3) is illuminated by means of light beams 7a and 7b, which are arranged so as to generate, at this surface 2a, a one-dimensional interference FIG. 6 consisting of interference fringes 6a (corresponding to the illuminated areas) and 6b (corresponding to the dark areas), as illustrated in FIG. 2,
to produce this interference FIG. 6, it is possible to use a holography device that comprises a light source illuminating firstly an object (in particular a mirror in a simple case) so that part of the light is diffracted (light beam 7b) to wards the surface 2a, and secondly a mirror so as to interfere with said diffracted light (by a light beam 7a) serving as a reference,
a one-dimensional (1D) interference FIG. 6 is then obtained after adjustment of the optical path differences.

With regard more particularly to the nanostructuring C) of the ZnO film 2, this is produced by photodissolution (or etching) in the illuminated areas 6a of the interference FIG. 6. In other word, there is generated, on the surface of the zinc oxide film 2 immersed in the aqueous solution, a topology corresponding to the pattern of the interference FIG. 6, this topology being produced by direct etching of the ZnO at the surface 2a thereof immersed in the illuminated areas 6b of the interference FIG. 6 (the etching being direct since it does not require a revelation step).

Concerning the etching speeds, under illumination at 40 mW/cm², it is possible to reach a speed of 40 milligrams per square metre minute (mg/m²min). Without illumination, the speed then becomes less than 10 mg/m²min: there is of course dissolution but this is slower.

The first embodiment of the method according to the invention consists finally of direct etching of the zinc oxide film 2 by means of the light beams 7a, 7b, which generate the interference FIG. 6. This makes it possible to limit the treated surface 2a of the film 2 of Zn only by the spatial extension of the beams, which depends only on the match between the power of the laser used and the dose necessary for etching. In this way the use of a mask is dispensed with completely, which opens the way to large-scale manufacturing methods.

### 2^{ND} EMBODIMENT OF THE METHOD ACCORDING TO THE INVENTION (WITH REFERENCE TO FIG. 3)

This method is similar to the method according to the first embodiment of the invention previously described (referring to FIGS. 1 and 2), to which an additional step B′ is added.

This additional step consists of generating an additional periodic nanostructure 8, in the same way as that generated in the first embodiment but turning the sample through 90°.

In this way two nanostructures 6 and 8 are obtained, which are arranged so as to form a two-dimensional structuring.

### 3^{RD} EMBODIMENT OF THE METHOD ACCORDING TO THE INVENTION (WITH REFERENCE TO FIG. 4)

This method is similar to the method according to the first embodiment of the invention previously described, apart from the fact that the nanostructuring of the film of zinc oxide takes place both by photodissolution in the illuminated area 6a and by growth in the dark area 6b of the interference FIGS. 6.

In this third embodiment of the method according to the invention, the reactions of growth (by crystallisation) and dissolution of the zinc oxide are in competition. To enable growth of zinc oxide crystals (at the interference 6 level) it is necessary to slightly favour the crystallisation reaction compared with the photodissolution. This is possible if the solution contains zinc 3.

Under the same conditions, it is possible to locally reverse the reaction by illumination, the crystals under illumination having better solubility because of the presence of photogenerated charge carriers, which makes it possible to limit or inhibit the growth of the crystals under illumination.

For this third embodiment above (involving competition between the growth and dissolution mechanisms), the two chemical and electrochemical methods are possible for effecting this nanostructuring.

Let us cite a few examples of conditions:
for the chemical method: hydrothermal growth under illumination in an aqueous solution comprising 0.025 M of zinc nitrate and diethylenetriamine,
for the electrochemical method (anodisation): an electrolyte solution of 80 ml of 5 mM ZnCl₂ and 0.1 M KCl, at a pH of 7 (photodissolution).

1. A method for nanostructuring a film of material (2), comprising a step of immersing said film of material (2) in an aqueous solution (3), during which there is applied, to at least one of the faces of the film (2), an interference FIG. (6) comprising illuminated areas (6b) and dark areas (6a),
said method being characterised in that:
said material is a semiconductor inorganic material or oxide, which is able to be solubilised in an aqueous solution under the effect of the absorption of light, and
the nanostructuring of the film or wafer of material (2) takes place, at the surface of the film (2) in contact with the aqueous solution (3), by photodissolution in said illuminated areas (6a) and/or by growth in said dark areas of said interference FIG. 6).

2. A method according claim 1, characterised in that the material (2) is non-porous.

3. A method according to claim 1, characterised in that the material (2) has a prohibited band energy in a wavelength domain corresponding to ultraviolet.

4. A method according to claim 1, characterised in that the material (2) comprising zinc oxide.

5. A method according to claim 1, characterised in that the nanostructuring of the film or wafer (2) takes place by photodissolution in the illuminated areas (6b) of the interference FIG. 6), in an aqueous solution the pH of which is between 6 and 12.

6. A nanostructured coating film (5) able to be obtained according to a preparation method as defined in claim 1.

7. A three-dimensional nanostructured coating film (5).

8. A method according to claim 2, characterised in that the material (2) has a prohibited band energy in a wavelength domain corresponding to ultraviolet.

9. A method according to claim 2, characterised in that the material (2) comprising zinc oxide.

10. A method according to claim 3, characterised in that the material (2) comprising zinc oxide.

11. A method according to claim 2, characterised in that the nanostructuring of the film or wafer (2) takes place by photodissolution in the illuminated areas (6b) of the interference FIG. 6), in an aqueous solution the pH of which is between 6 and 12.

12. A method according to claim 3, characterised in that the nanostructuring of the film or wafer (2) takes place by photodissolution in the illuminated areas (6b) of the interference FIG. 6), in an aqueous solution the pH of which is between 6 and 12.

13. A method according to claim 4, characterised in that the nanostructuring of the film or wafer (2) takes place by photodissolution in the illuminated areas (6b) of the interference FIG. 6), in an aqueous solution the pH of which is between 6 and 12.

14. A nanostructured coating film (5) able to be obtained according to a preparation method as defined in claim 2.

15. A nanostructured coating film (5) able to be obtained according to a preparation method as defined in claim 3.

16. A nanostructured coating film (5) able to be obtained according to a preparation method as defined in claim 4.

17. A nanostructured coating film (5) able to be obtained according to a preparation method as defined in claim 5.
